(19) United States
(12) Patent Application Publication
(10) Pub. No.: US 2004/0209198 A1
(43) Pub. Date: Oct. 21, 2004

(54) Method for fabricating patterns of reflective TFT-LCD using a transcribing mold

(76) Inventors: Yung-Chang Chen, Miao-Li (TW); Jia-Pang Pang, Miao-Li (TW); Chien-Ting Lai, Miao-Li (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/827,798

(22) Filed: Apr. 19, 2004

(30) Foreign Application Priority Data
Apr. 18, 2003 (TW) 92109037

(51) Int. Cl. B05D 5/06; G03F 7/00

(52) U.S. Cl. 430/320; 427/162; 427/282; 430/330

(57) ABSTRACT

A method for fabricating patterns of a reflective thin film transistor liquid crystal display (TFT-LCD) includes: providing a substrate (300); forming a TFT layer (310) on the substrate; coating a photo resist layer (320) on the TFT layer; pre-baking the photo resist layer; patterning the photo resist layer with a transcribing mold (400) having specific patterns; and further baking the photo resist layer. By using the transcribing mold, the shapes, precision and angles of the patterns can be accurately controlled, thereby easily providing a desired photo resist layer.

### BACKGROUND OF THE INVENTION

1. Field of the Invention

The present invention is related to methods for fabricating patterns of a reflective thin film transistor liquid crystal display (TFT-LCD), and more particularly to a method for carving a photo resist layer using a mold having specific patterns.

2. Description of Prior Art

TFT-LCDs (hereinafter, “LCDs”) can be divided into two main groups: transmissive LCDs and reflective LCDs. Most LCDs are of the transmissive type. These LCDs employ a light source called a “backlight” at a rear side; that is, behind the liquid crystal panel. Transmissive LCDs are thin and light, and are used in a variety of application fields. On the other hand, transmissive LCDs consume large amounts of power in order to keep the backlight illuminated. Even though only a small amount of power is consumed in order to adjust transmittance of the liquid crystals in the LCD, a relatively large amount of power is consumed overall. In addition, transmissive LCDs typically suffer from a phenomenon known as “wash-out.” That is, ambient light is brighter than the luminance of the display itself, so that the display cannot be clearly viewed. This phenomenon is particularly evident when a color transmissive LCD is used under circumstances where the ambient light is very strong and the display light is relatively weak. The problem can be overcome by using a brighter backlight. However, power consumption is further increased by such solution.

Unlike in a transmissive LCD, the display light obtained for a reflective LCD is proportional to an amount of the ambient light. Therefore the reflective LCD does not wash out even in a very bright environment. Furthermore, a reflective LCD does not need a backlight, thereby saving on power consumption. For the above reasons, reflective LCDs are particularly suitable in devices used outdoors, such as in portable information terminals, digital cameras and portable video cameras.

A light device called a “front light” has also been developed as an auxiliary light for reflective LCDs. A front light module is placed between a liquid crystal layer and a diffuser. The front light detects when ambient light is not sufficient, whereupon the front light is powered on automatically. The extra light ensures that the LCD can be clearly viewed. Reflective LCDs incorporating front lights are now widely used because of their efficacy in situations where the ambient light is weak. These reflective LCDs provide reflective films or patterns on the TFT layer, in order to reflect light that originates from the ambient environment. The patterns need to be precisely formed in order to provide the desired reflective angles, shapes and configurations. For fabricating the reflective films or patterns, semiconductor methods have been widely used in recent times. FIG. 5 shows a conventional photo resist layer 120 used in a reflective LCD, whereby external light (not labeled) is reflected by patterns 130 of the photo resist layer 120.

Referring to FIGS. 6 and 7, a conventional semiconductor method for fabricating patterns of a reflective LCD comprises the following steps: providing a substrate 100; forming a TFT layer 110 on the substrate 100 by repeatedly depositing, exposing, developing and etching material; coating the photo resist layer 120 on the TFT layer 110; pre-baking the photo resist layer 120; exposing the photo resist layer 120; developing the photo resist layer 120; etching the photo resist layer 120; and finally further baking the photo resist layer 120.

Further details are as follows. First, the substrate 100 can be glass or plastic. Second, the TFT layer 110 can be formed by way of lithography. The TFT layer 110 is an element used to control the luminance of the backlight module. Third, the photo resist layer 120 is coated on the TFT layer 110. Then a mask 200 is used to transfer patterns thereof (not labeled) to the photo resist layer 120, thereby forming specific patterns 130 in the photo resist layer 120.

Processing time, solvent concentration and contamination are some of the key factors critical to successful semiconductor methods. If any of these key factors errs, the final product fails. That is, it is inherently difficult to precisely control the shapes and angles of patterns 130 to provide the desired uniformly patterned photo resist layer 120. What is needed is a method that is more reliable than conventional semiconductor methods.

### SUMMARY OF THE INVENTION

It is an object of the present invention to provide a method for precisely fabricating patterns of a reflective TFT-LCD so that a uniformly patterned photo resist layer thereof can be reliably obtained.

In order to achieve the object set out above, a method for fabricating patterns of a reflective TFT-LCD comprises the steps of: providing a substrate; forming a TFT layer on the substrate; coating a photo resist layer on the TFT layer; pre-baking the photo resist layer; patterning the photo resist layer with a transcribing mold having specific patterns; and further baking the photo resist layer.

Other objects, advantages and novel features of the present invention will be apparent from the following detailed description of preferred embodiments thereof with reference to the attached drawings.

### BRIEF DESCRIPTION OF THE DRAWINGS

FIG. 1 is an isometric view of an unpatterned TFT substrate in accordance with the present invention.

FIG. 2 is similar to FIG. 1, but showing a transcribing mold being used to pattern a photo resist layer in the TFT substrate.

FIG. 3 is similar to FIG. 1, but showing the photo resist layer of the TFT substrate duly patterned.

FIG. 4 is a side elevation of FIG. 3.

FIG. 5 is a side elevation of a conventional patterned photo resist layer, showing light reflected by the patterns thereof.

FIG. 6 is an isometric view showing light exposure through a mask during process of lithography used to make the photo resist layer of FIG. 5, also showing the photo resist layer as part of a stacked TFT substrate.

FIG. 7 is a side elevation of the TFT substrate of FIG. 6.

### DETAILED DESCRIPTION OF THE PRESENT INVENTION

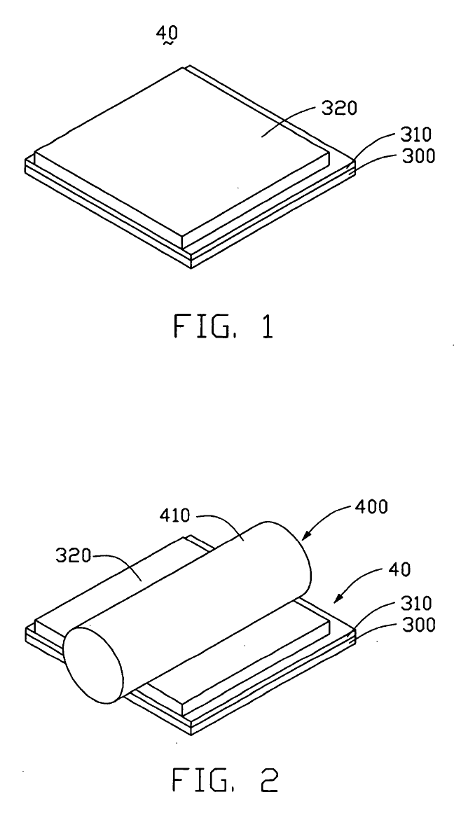

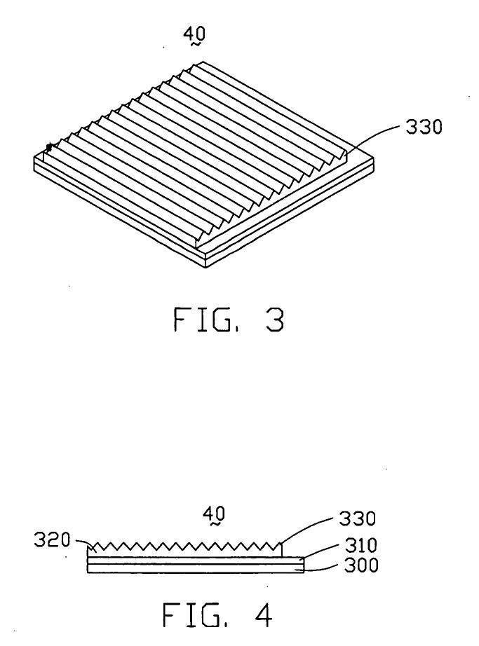

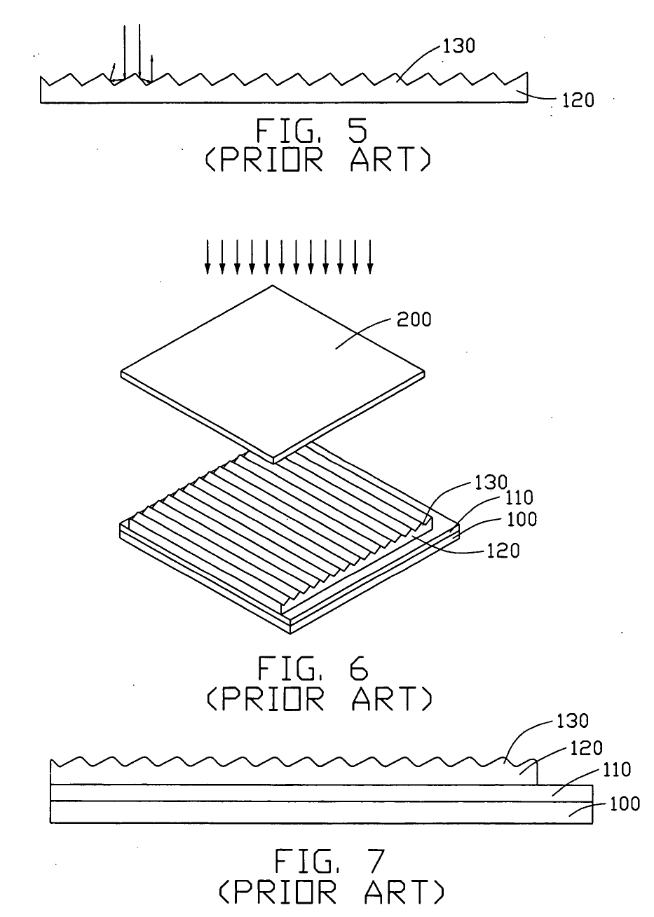

Referring to FIGS. 1 and 2, a substrate 300, a TFT layer 310 and a photo resist layer 320 are stacked one on the other from bottom to top in that order to form an unpatterned TFT substrate 40. The photo resist layer 320 is preferably made of organic material. Referring to FIGS. 3 and 4, patterns 330 have been formed in the photo resist layer 320 by etching.

The process of fabricating patterns of a reflective LCD is as follows. The first step is to provide the substrate 300, which can be made of resin or glass depending on the processing temperatures subsequently used. The TFT layer 310 is formed on the substrate 300 by depositing, developing and etching. The photo resist layer 320 is formed on the TFT layer 310, which can be accomplished by way of a spin method. The photo resist layer 320 is pre-baked. Specific patterns are transcribed from a transcribing mold 400 onto the photo resist layer 320 to form the desired patterns 330 thereon. Finally, the photo resist layer 320 is further baked to stabilize it.

In the above transcribing step, the transcribing mold 400 is cylindrical, and is made from high-hardness metallic material. The transcribing mold 400 has a cylindrical surface 410 with specific patterns (not shown) thereon. The desired patterns 330 formed on the photo resist layer 320 can vary according to need. For example, a profile of the patterns 330 may be sawtooth-shaped, triangular, semicircular, arcuate, and so on. The patterns 330 can be arranged as a regular array.

Unlike in the prior art, the present invention uses the high precision transcribing mold 400 to form the desired patterns 330 of the photo resist layer 320. It is therefore relatively easy to control the shapes, precision, and angles of the patterns 330. The transcribing mold 400 enables the photo resist layer 320 to be patterned highly uniformly.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for fabricating patterns for a reflective backlight, comprising the steps of:
providing a substrate;
forming a thin film transistor (TFT) layer on the substrate;
coating a photo resist layer on the TFT layer;
pre-baking the photo resist layer;
patterning the photo resist layer with a transcribing mold having specific patterns; and
further baking the photo resist layer.

2. The method as described in claim 1, wherein the substrate is made of glass.

3. The method as described in claim 1, wherein the substrate is made of resin.

4. The method as described in claim 1, wherein the photo resist layer is made of organic material.

5. The method as described in claim 1, wherein the transcribing mold is cylindrical.

6. The method as described in claim 5, wherein the specific patterns are on a surface of the transcribing mold.

7. The method as described in claim 1, wherein patterns of the photo resist layer are sawtooth-shaped.

8. The method as recited in claim 1, wherein patterns of the photo resist layer are triangular.

9. The method as described in claim 1, wherein patterns of the photo resist layer are semicircular.

10. The method as described in claim 1, wherein patterns of the photo resist layer are arcuate.

11. A method for fabricating patterns for a reflective backlight, comprising the steps of:
providing a substrate;
forming a thin film transistor (TFT) layer on the substrate;
coating a photo resist layer on the TFT layer;
pre-baking the photo resist layer;
forming protruding configurations on said photo resist layer via a mechanical process; and
further baking the photo resist layer.
